(19) United States
(12) Patent Application Publication
(10) Pub. No.: US 2026/0003215 A1
(43) Pub. Date: Jan. 1, 2026

(54) NON-VOLATILE OPTICAL MEMORY

(71) Applicant: HEWLETT PACKARD ENTERPRISE DEVELOPMENT LP, Spring, TX (US)

(72) Inventors: YUAN YUAN, Milpitas, CA (US); YIWEI PENG, Milpitas, CA (US); STANLEY CHEUNG, Milpitas, CA (US)

(21) Appl. No.: 18/898,260

(22) Filed: Sep. 26, 2024

Related U.S. Application Data
(60) Provisional application No. 63/665,963, filed on Jun. 28, 2024.

(51) Int. Cl. G02F 1/015; G02F 1/025; G06N 3/067; G11C 13/04

(52) U.S. Cl. CPC G02F 1/0152; G02F 1/0153; G02F 1/025; G06N 3/0675; G11C 13/047; G02F 2202/103; G02F 2203/15

(57) ABSTRACT

Systems and methods are provided for non-volatile optical storage devices that leverage photon avalanche-induced carrier trapping in semiconductor materials. Examples herein include a crystalline semiconductor layer disposed on a substrate and an amorphous layer disposed on the crystalline semiconductor layer. The crystalline semiconductor layer comprises an optical waveguide and a PN junction formed in the optical waveguide. An optical source is configured to emit light of a wavelength into the optical waveguide and a power source is configured to supply a first voltage bias across the PN junction that causes an amplitude of optical power of light emitted from the optical waveguide to change from a first amplitude to a second amplitude. The optical waveguide emits light at the second amplitude while the first voltage bias is supplied and after the first voltage bias is removed.

### CROSS REFERENCE TO RELATED APPLICATIONS

This application claims the benefit of and priority to U.S. Provisional Patent Application No. 63/665,963, filed on Jun. 28, 2024, the contents of which are incorporated herein by reference in their entirety.

### BACKGROUND

Developments in large-scale data processing have increased demands for high levels of computing performance, for example, in large-scale data processing and artificial intelligence (AI) applications. Optical computing, which leverages optical technology to achieve increased transmission speed and energy efficiencies compared to traditional electrical methods, can accelerate computation performance. Optical computing uses light waves produced by optical sources, such as lasers or incoherent sources, for data processing, data storage, and/or data communication for computing applications.

### BRIEF DESCRIPTION OF THE DRAWINGS

The present disclosure, in accordance with one or more various examples, is described in detail with reference to the following figures. The figures are provided for purposes of illustration only and merely depict typical, non-limiting aspects of such examples.

FIG. 1 depicts a schematic block diagram of an example optical system in accordance with implementations disclosed herein.

FIGS. 2A and 2B depict schematic diagrams of an example optical storage device in accordance with an implementation disclosed herein.

FIG. 3 illustrates a schematic diagram of an imperfect transition between crystalline and amorphous materials at an interface of the optical storage device of FIGS. 2A and 2B.

FIGS. 4A and 4B illustrate schematic diagrams of set and reset operation of the optical storage device of FIGS. 2A and 2B.

FIGS. 5A-5E illustrate example band diagrams, current density distributions, free charge carrier concentrations, and trap occupation probability during set and reset operations in accordance with an example disclosed herein.

FIGS. 6A-6C depict examples of shifts in resonant frequencies and retention capabilities of an optical storage device, in accordance with an example disclosed herein, in set and reset states.

FIGS. 7A and 7B depict examples of a plurality of set states of an optical storage device in accordance with an example disclosed herein.

FIGS. 8A-8C depict an example optical neural network utilizing optical storage devices in accordance with the examples disclosed herein.

FIG. 9 is an example computing component that may be used to implement various features of non-volatile optical storage in accordance with the implementations disclosed herein

FIG. 10 is a computing component that may be used to implement examples of the disclosed technology.

The figures are not exhaustive and do not limit the present disclosure to the precise form disclosed.

### DETAILED DESCRIPTION

As alluded to above, implementing on-chip non-volatile optical memories has long been an actively pursued goal, promising significant enhancements in the capability and energy efficiency of photonic integrated circuits. Examples disclosed manipulate a photon avalanche effect that introduces a carrier trapping effect at an interface between differing semiconductor materials. The interface, according to examples disclosed herein, may be formed between a first semiconductor material, in which the photon avalanche effect can be induced, and a second semiconductor material. The carrier trapping effect in turn demonstrates a non-volatile reprogrammable optical memory cell through a non-volatile wavelength shift. As used herein, “non-volatile” refers to an ability to retain (e.g., store) a state even in the absence of supplied power or voltage. In illustrative examples, the first semiconductor material may be commonly used crystalline semiconductor materials, such as, but not limited to, silicon (Si), indium phosphide (InP), aluminium gallium arsenide (AlGaAs), gallium arsenide (GaAs), and the like, while the second semiconductor material may be a commonly used an amorphous material, such as, but not limited to, silicon dioxide (SiO₂), silicon nitride (Si₃N₄), aluminium nitride (AlN), and aluminum oxide (AlO₃), or the like. In this case, the Si based avalanche-induced trapping memory can provide cost-efficient and high-reliability optical data storage in traditional silicon foundry processes.

As alluded to above, optical computing may be leveraged to accelerate computing performance. Optical computing has focused on replacing conventional electrical computer components with optical equivalents, resulting in an optical digital computer system. For example, high-speed optical interconnects have been implemented in computing architectures, as well as optical neuromorphic computing chips. The result is the integration of optical components into traditional computers that provides optical-electronic hybrid computing. However, such devices are subject to optical-electrical-optical (OEO) conversions, in which optoelectronic devices consume energy converting electronic energy into photons and back, which delays computations. For example, when information is stored on a random access memory (RAM) and flash memory implemented using electronic integrated circuits (EICs), retrieval of the stored information may necessitate OEO conversions due to communication between the PICS and EICs. The OEO conversions cause latency that can constrain the computation speed (e.g., in terms of operations per second) and can prevent the PIC from realizing its full capability.

All-optical computers can eliminate the need for OEO conversions, thereby minimizing static power consumption. For example, optical storage devices (also referred to herein as optical memories) can minimize and possibly eliminate OEO conversion instances due to data exchanges with electrically-based storage devices, which can eliminate the corresponding latencies and static energy consumption. Thus, optical storage could boost performance of optical computing systems. Furthermore, optical storage can be used to eliminate the von-Neumann bottleneck by reducing the traffic between the PIC and EIC, and facilitate system architectures such as spiking neural networks and in-memory optical computing.

Yet, unlike random access memory (RAM) and flash memory implemented using electronic integrated circuits (EICs), optical memory has proven to be difficult to implement on photonic integrated circuits (PICs), which poses a challenge to storing information within PICs. For example, optical storage devices have proven to be difficult to implement due to the weak interaction of photons. For example, photons may have difficulty interacting with each other in the way electrons do. Photons are bosons and they can occupy the same state without exclusion, which means they can superimpose without affecting each other. Accordingly, it can be difficult to control/store photons, which may be a barrier in providing optical memories in the conventional approaches.

Efforts have been made to develop optical storage devices. Similar to electronically-based storage, optical storage device can be classified into two main categories: volatile and non-volatile. Volatile optical storage devices, that lose the stored data when power is off, can be implemented through bi-stable optical devices, optical ion excitation, and recirculating loop arrangements. Non-volatile optical memories, on the other hand, can maintain the stored data without power. Non-volatile optical storage devices can be achieved by altering the material properties interacting with light, including phase-change memories (PCMs), ferroelectric memories, micro-electro-mechanical systems (MEMS), floating-gate memories, and optical memristors.

PCMs can be characterized by thermal energy-dependent properties, transitioning between amorphous and crystalline states. This reversible transformation can lead to changes in optical properties, affecting both the real and imaginary components of the complex refractive index. Conventionally, PCMs utilize germanium-antimony-tellurium alloy (GST), which can require additional fabrication processes, such as sputtering, on PICs.

Ferroelectric memories can toggle between two polarization states. However, this can require additional integration of ferroelectric materials, such as lead zirconium titanate (PZT), barium titanate (BTO), polyvinylidene flouride (PVDF), and hafnium oxide (HfO₂), on PICs.

MEMS devices employ various mechanisms, such as electrostatic, electrothermal, electromagnetic, and piezoelectric methods. Electrostatic actuation, in particular, can allow low-power MEMS on a Si platforms. Efforts have been dedicated to integrating MEMS into the traditional Si photonics process, progressing from multi-layer MEMS to single-layer MEMS. However, the movable parts of MEMS may still necessitate several additional fabrication processes for deployment. Additionally, switching voltages of MEMS tend to be relatively very high.

Optical floating-gate memories, akin to their electrical counterparts, involve a thin oxide dielectric layer and a floating gate, which are compatible with complementary-metal-oxide-semiconductor (CMOS) technology. The application of a bias voltage to the floating gate induces a high electric field, facilitating carrier injection into the oxide layer. Consequently, the reflective index of the device undergoes changes owing to the plasma dispersion effect. However, optical floating-gate memories may also require additional doping and bonding processes of Group III-V material to traditional Si photonic foundries.

Optical memristors may also be CMOS-compatible, which can be integrated on Si PICs through heterogeneous integration. However, similar to floating-gate memories, these device may require an extra memristor layer, such as HfO₂, zinc oxide (ZnO), titanium dioxide (TiO₂), tungsten oxide (WOₓ), and tantalum pentoxide (Ta₂O₅). Besides that, the yield and reliability of memristors still face challenges. For example, memristors may be sensitive to small variations in the fabrication process, leading to inconsistent device characteristics and variability in fabrication. Memristors may also rely on material properties and the impurities in the material can lead to defects, impacting the yield. Additionally, memristors can exhibit stochastic switching characteristics and the transition between resistance states is not always consistent, which leads to switch variability.

Unlike the aforementioned efforts, examples disclosed herein provide for non-volatile optical storage devices that leverage photon avalanche-induced carrier trapping using common semiconductor materials, such as Si. By leveraging Si instead of PCM materials, ferroelectric materials, Group III-V material, memristors materials, examples herein can be integrated into traditional Si photonics foundries, thereby providing a cost-efficient means for producing non-volatile optical memory at high-yield on Si implemented PICs.

Examples of the presently disclosed technology provide a non-volatile optical storage device that comprises a crystalline semiconductor layer disposed on a substrate. In various examples, the crystalline semiconductor layer comprises Si. In other examples, the crystalline semiconductor layer may also comprise indium phosphide (InP), aluminium gallium arsenide (AlGaAs), gallium arsenide (GaAs), and/or the like. In an illustrative example, the crystalline semiconductor layer is substantially (e.g., including negligible amounts of trace materials) or entire composed of Si. An optical waveguide can be formed in the crystalline semiconductor layer and a PN junction can be formed in the optical waveguide. For example, the PN junction can be formed by doping a first portion of the waveguide with p-type dopants and a second portion of the waveguide can be doped with n-type dopants. This doping of the optical waveguide integrates a PN junction within the optical waveguide at a first interface (also referred to as a depletion interface) between the first and second portions thereof. In examples, an amorphous layer can be disposed on the crystalline semiconductor layer forming a second interface. The amorphous layer may be referred to as an insulating or passivation layer, in some examples. In an illustrative example, the amorphous layer may comprise silicon dioxide (SiO₂). However, other materials may be used, such as but not limited to, silicon nitride (Si₃N₄), aluminium nitride (AlN), and aluminum oxide (AlO₃). The amorphous layer may be referred to as an insulating or passivation layer, in some examples.

Defect sites can form at the second interface due to the imperfect interface between the crystalline and amorphous materials that generate dangling bond carrier traps. These dangling bond carrier traps (also referred to as carrier traps or traps) can be leveraged to induce non-volatile plasma dispersion based wavelength shifts that can provide for non-volatile optical storage. For example, light at an input wavelength can be input into the optical waveguide, for example, by an optical source emitting the light that can be coupled into the optical waveguide. A first voltage bias (also referred to herein as a set voltage bias) can be applied across the PN junction by a power source. Applying the first voltage bias, while the light propagates in the optical waveguide, can cause a photon avalanche induced increase in free charge carrier concentration at the first interface. The increase in free charge carrier concentration can lead to an accumulation of free charge carriers trapped at the second interface (sometimes referred to herein as an insulating interface) between the crystalline semiconductor layer and the amorphous layer in the carrier traps between. The free charge carriers may remain permanently trapped in the carrier traps irrespective of whether or not the first voltage bias is supplied after trapping. The accumulation of trapped carriers at the second interface can induce a non-volatile change in a refractive index of the optical waveguide. For example, the trapped carriers can cause a non-volatile plasma dispersion effect that permanently (e.g., until a reset voltage bias is applied) alters the refractive index of the waveguide and causes a non-volatile change in optical power output (e.g., amplitude or level) from the optical waveguide, for example, due to refractive index induced absorption.

To reset the device, the power source can then be operated to supply a second voltage bias (also referred to herein as a reset voltage bias) at an opposing polarity relative to the first voltage bias, which reverts the wavelength of the light back to the input wavelength. For example, applying the second voltage bias may release the trapped free charge carriers. The release of the carriers can cause the refractive index of the optical waveguide to return to its original state (e.g., original value) and the level of the optical power output by the optical waveguide returns to the initial level.

As used herein, the term “permanently” means that a state lasts or remains unchanged indefinitely, without interruption, under certain conditions. When the conditions change, the state may change. For example, as described above, the first voltage bias may change a condition of the disclosed examples to cause an accumulation of trapped carriers. When the first voltage bias is removed, the trapped carriers remain trapped permanently, at least until conditions on the disclosed devices change. For example, applying a second voltage bias (e.g., the reset voltage bias) changes the conditions applied to the disclosed devices such that the trapped carriers can be released, thereby changing the state of the non-volatile memory device under altered conditions.

In electrically-based charge trapping memory (CTM) devices, charge trapping can lead to bias temperature instability (BTI). BTI has become increasingly problematic as sizes of metal-oxide-semiconductor field effect transistors (MOSFETs) shrink. For example, when a gate of a heated MOSFET is heavily biased, a strong electric field through the oxide layer can result in the degradation of the MOSFET threshold voltage. This degradation of the MOSFET threshold has been tied to charge trapping. However, while BTI poses a challenge in electrically-based CMT devices, the optical storage devices disclosed herein do not include a gate or vertical electric field on an oxide layer. Instead, traps at the second interface can be charged by unbalanced free charge carriers originating from the photon avalanche effect, which can avoid a high electric field and the resulting instability. The disclosed examples provide for a hysteresis effect on the second interface, imparting non-volatile switching characteristics to the optical storage device. Set and reset states (also referred to as program and erasure states) of the disclosed device can be implemented through the P-N junction, which can ensure compatibility with existing photonics devices.

Consequently, the examples disclosed herein can be utilized to realize photonic data storage. By leveraging traditional fabrication process, the disclosed examples provide a simple, cost-efficient, and high-yield pathway to integrate optical storage device into PICs that can be applicable in areas such as optical interconnects, optical computing, and photonic quantum circuits.

In the claims that follow, the term “approximately” is used with certain voltages or currents. The term “approximately” refers to a range in around a specific value. For example, approximately the breakdown voltage may mean any voltage±0.1 volts from the breakdown voltage.

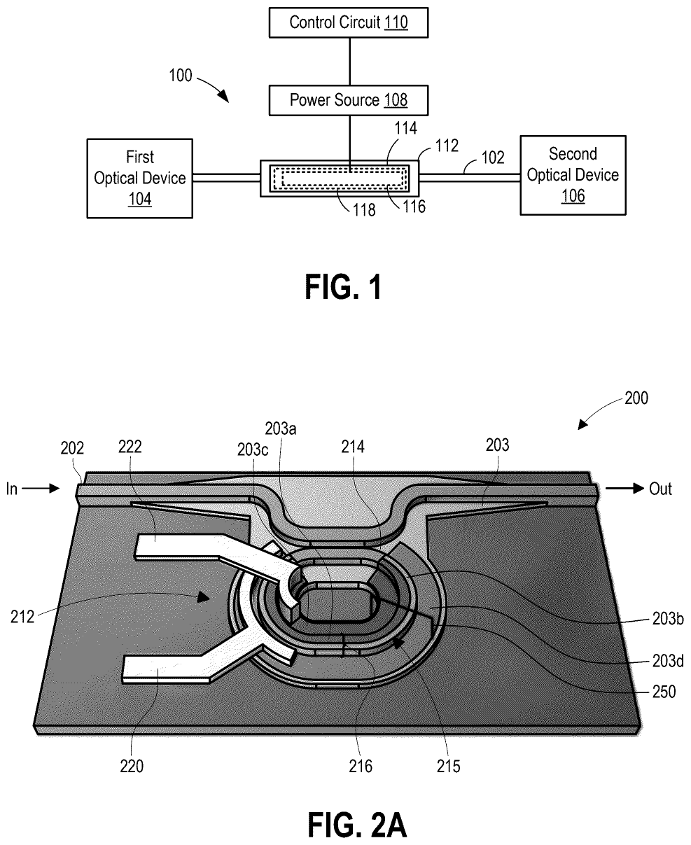

FIG. 1 depicts a schematic block diagram of optical storage system 100 in accordance with implementations disclosed herein. The optical storage system 100 may include a plurality of optical devices capable of generating, processing, and/or allowing passage of an optical signal (e.g., light). In the example of FIG. 1, the optical storage system 100 includes a light-conducting medium 102, a first optical device 104, a second optical device 106, one or more power source 108, a control circuit 110, and a non-volatile optical storage device 112 (also referred to herein as an optical storage device 112).

The light-conducting medium 102 may comprises a waveguide such as a semiconductor waveguide. In various examples, optical storage system 100 may be formed in a silicon-based photonic chip of a silicon-on-insulator (SOI) platform. In this case, the waveguide may be formed of a common semiconductor material, such as crystalline Si.

The first optical device 104 may comprises an optical device capable of generating and/or processing optical signals. Examples of the first optical device 104 may include, but are not limited to, a light source, an optical amplifier, an optical modulator, an optical splitter, an optical combiner, an optical coupler, an optical filter, an optical resonator, or a photodetector. Furthermore, the second optical device 106 may comprise an optical device capable of generating and/or processing the optical signals. Examples of the second optical device 106 may include, but are not limited to, an optical amplifier, an optical modulator, an optical splitter, an optical combiner, an optical coupler, an optical filter, an optical resonator, a photodetector, or the like. In various examples, the first optical device 104 may be a light source configured to emit light at an input wavelength and the second optical device 106 may be any device capable of processing optical signals output by the light-conducting medium 102.

According to examples disclosed herein, optical storage device 112 may aid in non-volatile tuning of light propagating in the light-conducting medium 102. For example, optical storage device 112 can be optically coupled to the light-conducting medium 102 and operated to induce a non-volatile shift in the optical power of the light propagating thereon. Optical storage device 112 may be connected to power source 108 operated by control circuit 110. The power source 108 can be controlled to supply a first voltage bias to the optical storage device 112 that causes the non-volatile shift of the optical power of the light propagating long the light-conducting medium 102 from a first amplitude to a second amplitude. In an example, first optical device 104 may emit light into the light-conducting medium 102 at the input wavelength. The optical storage device 112 may induce a non-volatile shift that shifts the optical power of the light on the light-conducting medium 102 to a second amplitude, which can then be output to the second optical device 106 for processing.

In examples disclosed herein, the shift can be caused by an accumulation of carrier trappings induced by a photon avalanche effect within the optical storage device 112, as described below in greater detail. The carrier trapping may be exhibit non-volatile characteristics that changes the refractive index of the light-conducting medium 102 in a manner that is permanent until a reset voltage bias is applied to the optical storage device 112.

In an illustrative example, optical storage device 112 may comprise an optical waveguide 114 having a PN junction 116 integrated therein. The optical waveguide 114 may be formed from of a common semiconductor material, such as crystalline Si. In some examples, the crystalline semiconductor layer can be substantially (e.g., including negligible amounts of trace materials) or entirely composed of Si. The PN junction 116 can be formed by doping a first portion of the optical waveguide with a first type of dopants (e.g., p-type dopants in one example) and a second portion of the optical waveguide can be doped with a second type of dopants (e.g., n-type dopants in one example). A layer of amorphous material 118 can be disposed on the optical waveguide 114 forming a second interface. In an illustrative example, the amorphous material 118 may comprise silicon dioxide (SiO₂). However, other materials may be used, such as but not limited to, silicon nitride (Si₃N₄), aluminium nitride (AlN), and aluminum oxide (AlO₃).

Defect sites can form at the second interface due to an imperfect interface between the optical waveguide 114 and amorphous material 118 that generate dangling bond carrier traps. These dangling bond carrier traps (also referred to as carrier traps or trap) can be leveraged to induce a non-volatile plasma dispersion effect based wavelength shift that can provide for non-volatile optical storage. For example, light at an input wavelength can be input into the optical waveguide 114, for example, via coupling with light-conducting medium 102. A first voltage bias (also referred to herein as a set voltage bias) can be applied across the PN junction 116 by the power source 108. Applying the first voltage bias, while light propagates in the optical waveguide 114, can cause a photon avalanche induced increase in free charge carrier concentration in the PN junction 116. The increase in free charge carrier concentration can lead to an accumulation of free charge carriers being trapped in the carrier traps at the second interface between the optical waveguide 114 and the amorphous material 118. The free charge carriers may remain permanently trapped in the carrier traps irrespective of whether or not the first voltage bias remains after trapping. The accumulation of trapped carriers at the second interface can induce a non-volatile change in a refractive index of the optical waveguide 114. For example, the trapped carriers can cause the non-volatile plasma dispersion effect that permanently (e.g., until a reset voltage bias is applied) alters the refractive index of the waveguide and causes a red shift in the wavelength.

To reset the optical storage system 100 (e.g., erase the non-volatile storage), the control circuit 110 may be operated to cause the power source 108 to supply a second voltage bias (e.g., the reset voltage bias) to a level that releases the trapped carriers. Releasing the trapped carriers resets the refractive index of the optical waveguide 114 and reverts the optical power of light on the light-conducting medium 102 to the first amplitude. In examples, the second voltage bias has a polarity opposite to that of the first voltage bias.

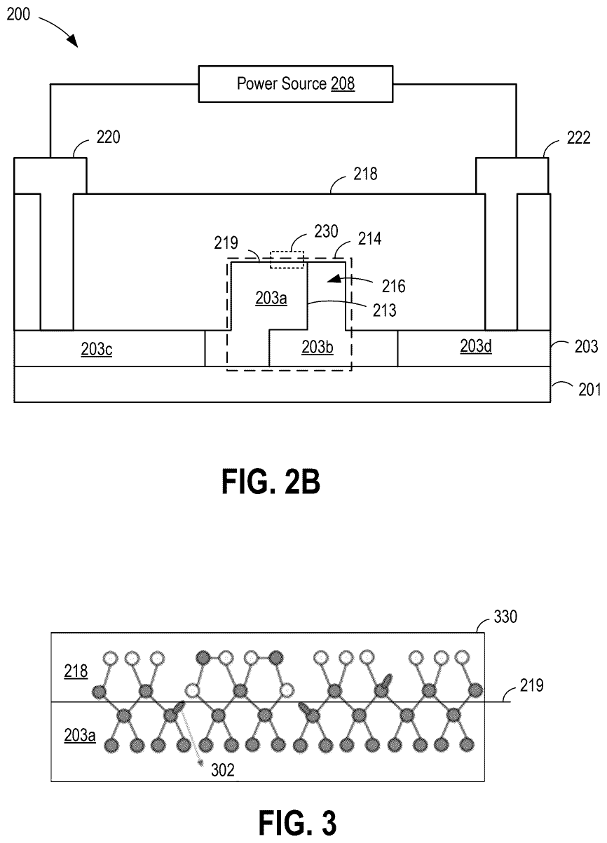

FIGS. 2A and 2B depict schematic diagrams of another example optical storage device 200 in accordance with an implementation disclosed herein. Optical storage device 200 may be an example of optical storage device 100 described above. FIG. 2A is a perspective view of the optical storage device 200 and FIG. 2B is a section view of the optical storage device 200 taken along a plane 250 shown in FIG. 2A. Optical storage device 200 includes a bus waveguide 202 optically coupled to a non-volatile optical storage device 212 via evanescent optical coupling. The bus waveguide 202 and non-volatile optical storage device 212 may be an example implementation of light-conducting medium 102 and non-volatile optical storage device 212 of FIG. 1.

In the illustrative example of FIGS. 2A and 2B, the optical storage device 200 includes a device layer 203 formed on a substrate 201. An optical waveguide 214 (illustratively represented as the dashed line in FIG. 2B) can be formed from the device layer 203, for example, by patterning/etching, monolithic growth, or other fabrication techniques. Optical waveguide 214 may be an example implementation of optical waveguide 114 of FIG. 1. The optical waveguide 214 may be a closed loop waveguide, as shown in FIG. 2A. The shape of the loop may be, for example but not limited to, circular, elliptical, stadium, etc., thereby forming resonator structure 215, which may be a ring resonator or cavity. The resonator structure 215 may be, according to various examples, a micro-ring resonator (MRR). The resonator structure 215 may have a resonant frequency that resonantly amplifies light propagating in the optical waveguide 214 at the resonant frequency and evanescently couples the light into and out of the bus waveguide 202 according a coupling coefficient based on the design specifications of the optical storage device 200. The device layer 203, according to examples herein, may comprise a crystalline semiconductor material. In various examples, device layer 203 may be a crystalline Si layer.

The device layer 203 may include a plurality of portions 203a-203d. The portions 203a-203d may be doped with a dopant. In examples, a first portion 203a and a third portion 203c may be doped with a first dopant type, while a second portion 203b and a fourth portion 203d may be doped with a second dopant type. For example, portions 203a and 203c may be doped with p-type dopants and portions 203b and 203d may be doped with n-type dopants. In examples, portion 203c and portion 230d may be doped with dopant concentrations that are higher than the dopant concentrations of the portion 203a and the second portion 203b, respectively. Accordingly, a PN junction 216 (e.g., PN junction 116 of FIG. 1) may be formed within (e.g., integrated into) optical waveguide 214 through doping of the portions 203a and 203b with dopants of opposing polarities. Doping the portions 203a and 203b can form a depletion interface 213 of the PN junction 216.

While certain portions of optical storage device 200 are described as doped with n-type or p-type dopants, implementations are not limited thereto, and the polarity of the dopants may be switched. For example, while the above example described the first and third portions 203a and 203c as doped with p-type dopants and the second and fourth portions 203b and 203d doped with n-type dopants, the polarity of each portion may be switched as desired.

Furthermore, the depletion interface is shown having a specific step-like shape. However, examples herein are not limited to the depletion interfaces of a specific shape. For example, a continuous linear depletion interface 213 may be formed in one example. In another example, the step-like shape may be reversed. The specific shape may be designed according to a desired application and characteristics of the PN junction.

An insulating or passivation layer 218 (not shown in FIG. 2A for illustrative purposes only) may be formed over the device layer 203, thereby encapsulating the optical waveguide 214, as well as the resonator structure 215. The insulating layer 218 may be formed from amorphous material, such as but not limited to, SiO₂, Si₃N₄, and AlO₃. As a result, a crystalline-amorphous interface 219 (also referred to as an insulating interface) can be formed between the insulating layer 218 (e.g., amorphous material 118 of FIG. 1) and the optical waveguide 214 (e.g., where the crystalline and amorphous materials contact each other).

The optical storage device 200 may also comprise contact electrodes 220 and 222 as contact terminals that can electrically connect power source 208 (e.g., power source 108 of FIG. 1) to portions 203c and 203d of the device layer 203, respectively. The contact electrodes 220 and 222 may be formed in vias through the insulating layer 218. In the illustrative example, the contact electrode 220 may function as an anode, for example, where portions 203a and 203c are doped with p-type dopants. In this example, contact electrode 222 may function as a cathode where portions 203b and 203d are doped with n-type dopants.

According to examples herein, power source 208 can be electrically connected to the PN junction 216. The power source 208 can be operated to apply a voltage bias across the PN junction 216, which can aid in inducing charge trapping at the interface 219 through the photon avalanche effect to achieve non-volatile optical storage. For example, a light traveling at a setting wavelength can be coupled into the resonator structure 215 via bus waveguide 202 and propagate in the optical waveguide 214. Adjusting the power source 208 to supply a setting voltage bias across the PN junction 216, while the light is propagating at the setting wavelength, can induce a non-volatile change in the resonant frequency of the resonator structure 215 via a non-volatile change in the refractive index of the optical waveguide 214. This change in the resonant frequency induces a wavelength shift of light that can resonate in the resonator structure 215. The light propagating in the resonator structure 215 can be coupled from the optical waveguide 214 into the bus waveguide 202 and output for downstream processing. The shift in resonant frequency may result in increased optical loss (e.g., absorption) of light propagating in the optical waveguide 214 at the input wavelength, thereby changing the amplitude of the optical power of light that is output from the resonator structure to the bus waveguide 202. Thus, information can be stored in the optical domain through non-volatile shift in the resonant frequency.

As alluded to above, the non-volatile change may be due to imperfect transitions between crystalline semiconductor material and amorphous material at the interface 219. The imperfect transition between crystalline and amorphous materials may lead to some unbonded atoms, creating unpaired electrons that localize on the defect atoms and form dangling bond traps.

For example, FIG. 3 illustrates a schematic diagram of an imperfect transition between crystalline and amorphous materials at the interface 219 of FIG. 2B. FIG. 3 illustrates a zoomed in view 330 of the region 230 of interface 219 shown in FIG. 2B. In the illustrative example shown in FIG. 3, the device layer 203 is formed from crystalline Si and the insulating layer 218 is formed from SiO₂. While FIG. 3 depicts portion 203a, the example discussed herein applies to the entirety of the interface 219. FIG. 3 depicts potential traps 302, which may be oxide trapping centers. The oxide trapping centers can comprise of an unpaired electron localized on a Si atom (shown as solid grey), while back-bonded to three oxygen atoms (shown as solid white). The potential traps 302 can have band gap levels near the middle of a SiO₂ bandgap, facilitating hole capture from the device layer 203, thereby exhibiting donor-like traps. These donor-like traps can be electrically neutral when empty and positively charged when occupied by holes. The occupation of the traps varies according to the stress conditions (e.g., voltage bias) applied to the optical storage device 200. When occupied, the charged traps can establish a localized electrical field that repels dopant charges of the same polarity in the device layer 203 waveguide away from the interface 219. This space charge distribution can relocate the doping profile of the PN junction 216, thereby changing the effective refractive index of the optical waveguide 214 through the plasma dispersion effect. As a result, by occupying/emptying the interface traps 302, the optical waveguide 214 exhibits different refractive indices and thus distinct resonant frequencies in its optical spectrum. In examples, a trap occupation ratio can change under different stress conditions, therefore, once this optical storage device 200 is programmed/erased, the optical storage device 200 can exhibit a multi-level non-volatile wavelength shift.

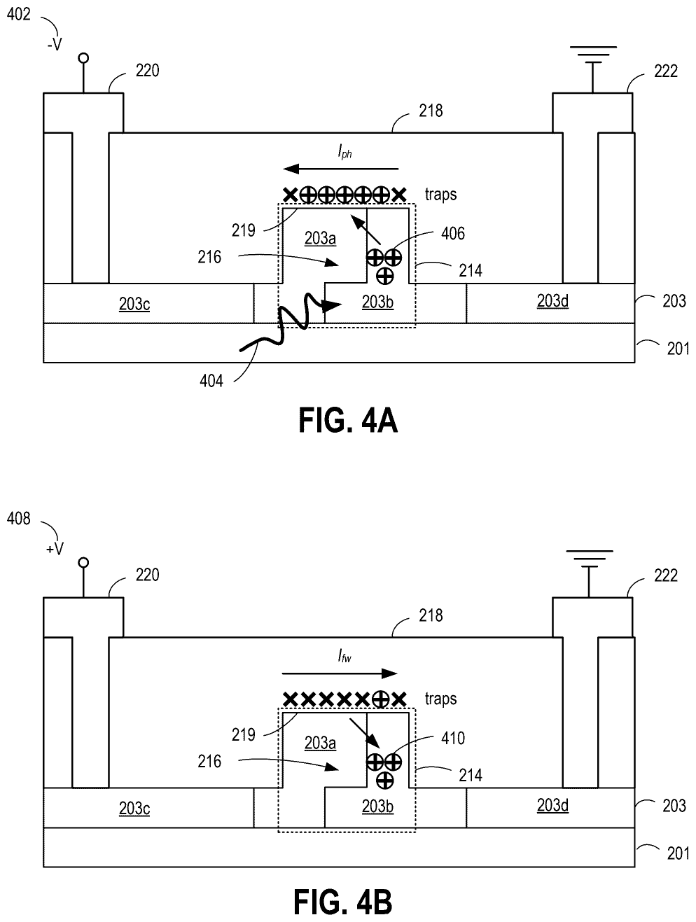

FIGS. 4A and 4B illustrate schematic diagrams of the setting (also referred to as programing) and resetting (also referred to as erasure) process of the optical storage device 200 described above. For example, FIG. 4A depicts conditions for setting the optical storage device 200 that can cause a change in the effective refractive index of the optical waveguide 214 by filling traps (e.g., traps 302 of FIG. 3) with free charge carriers 406. FIG. 4B depicts conditions for the reset process that can release the traps, thereby reallocating free charge carrier 410 and resetting the refractive index of the optical waveguide 214.

To program the optical storage device 200, a first voltage bias 402 (e.g., a setting voltage bias) can be applied across the PN junction 216 while an optical signal 404 is coupled into the resonator structure 215, and ultimately the optical waveguide 214 to program/set the optical storage device 200. An optical source (e.g., the first optical device 104 of FIG. 1 as an optical source) can be configured to input the optical signal into the bus waveguide 202 (shown in FIG. 2A), which can be evanescently coupled into the optical waveguide 214. In the example of FIG. 4A, first voltage bias 402 may be provided as a reverse voltage bias, supplied by power source 208, at approximately the avalanche breakdown voltage of the PN junction 216. The optical signal 404 (which may be referred to as a setting optical signal) may have a wavelength in the O-band of the electromagnetic spectrum (e.g., 1260 nm and 1360 nm) as a setting wavelength, such as emitted by an O-band laser. However, the optical signal 404 may have any desired wavelength along the electromagnetic spectrum. While lower wavelengths may be used for optical signal 404, some such wavelengths may be attenuated by the material of the optical waveguide (e.g., 800 nm light may be absorbed by Si, whereas Si is substantially transparent to wavelengths in the O-band). Thus, lower wavelengths may require higher input optical power in order to generate a photocurrent of sufficient magnitude.

Applying a reverse voltage bias as first voltage bias 402 at approximately the avalanche breakdown voltage of the PN junction 216 at the same time that the optical signal 404 is coupled into the optical waveguide 214, a photocurrent (Iₚₕ) can be generated that is of a sufficient magnitude to induce charge trapping. For example, generation of an Iₚₕ of greater than a photocurrent threshold can result can induce trapping of free charge carriers 406. In examples, the photocurrent threshold may be 50 HA. In some examples, the photocurrent threshold may be approximately 100 μA. The term “approximately” in this case refers to ±10 μA of from 100 μA. The photocurrent may be a result of the combination of photon-assisted tunneling in the optical waveguide 214, resonant enhancement in the resonator structure 215, and avalanche gain in the PN junction 216.

Due to a difference between holes and electron during impact ionization events (e.g., reverse bias stress) and drift velocity, an accumulation of free charge carriers 406 as positively charged holes may occur that results in a larger quantity of holes competed to electrons within the optical waveguide 214. When a sufficient photocurrent is generated under the above conditions, traps at the interface 219 may gradually capture these excess holes (e.g., free charge carriers 406). For example, as shown in FIG. 4A, accumulated free charge carriers 406 can be gradually captured in empty traps (shown in FIG. 4A as an “x” at the interface 219), resulting in filled trapped containing trapped carriers (shown in FIG. 4A as a “+” at the interface 219).

Accumulation of filled traps may redistribute the doping profile of the optical waveguide 214 in a non-volatile manner by accumulating positive charges at the interface 219. This accumulation of charges can induce the plasma dispersion effect that causes a change in the effective refractive index of the optical waveguide 214, resulting in the optical storage device 200 entering a set or programmed state. While in the set state, the optical storage device 200 may shift the wavelength of an input optical signal due to the changed effective refractive index. Once set, optical storage device 200 may exhibit the wavelength shift in the absence of an external power source applied thereto.

In some examples, if the generated photocurrent is not sufficient (e.g., below a threshold photocurrent), the wavelength shift may be reliant on the first voltage bias 402 alone, which may be relatively small and difficult to distinguish from un-shifted wavelength (e.g., the initial state). Said another way, a wavelength shift by the first voltage bias 402 alone may be indistinguishable from an input wavelength, particularly where noise is present. This may be due to an increase in concentration of free charge carriers 406 generated by impact ionization, which alone may not be sufficient lead to an accumulation of filled traps. The addition of photo-illumination by the optical signal 404 can aid in increasing the amount of extra free charge carriers 406 generated in the PN junction 216 due to a photon avalanche induced increase in free charge carriers 406.

In contrast, a voltage bias (e.g., electrical stress) alone may be sufficient to release free charge carriers from the traps to provide a reset process (e.g., erasure). For example, as shown in FIG. 4B, a second voltage bias 408 (e.g., a forward voltage bias) can be applied to the PN junction 216 that generates a forward current I_{fw}. If the forward current I_{fw} is sufficiently large (e.g., above a current threshold), the forward current I_{fw} may operate to discharge the filled traps and release trapped free charge carriers. The free charge carriers can migrate back into the optical waveguide 214 as released free charge carriers 410. The current threshold in some examples may be around hundreds of μA. As a result of the redistribution of free charge carriers 410, the doping profile of the optical waveguide 214 can be reset to the initial state (e.g., the effective index of refraction can be reset to an original value).

As described above, the imperfect interface 219 transition between the crystalline semiconductor material of the device layer 203 and the amorphous material of the insulating layer 218 can introduce dangling bond traps that undergo filling and emptying during set and reset operations. The following charge switch of traps results in the hysteresis effect of the PN junction-based waveguide 214. The transient behavior of traps can be described by the following rate equation:

$$\frac{d {F}_{t D}}{dt} = [ P ( 1 - {F}_{tD} ) - {F}_{d e g} {F}_{tD} {n}_{i} exp ( \frac{{E}_{t D} - {E}_{i}}{{k}_{B} T} ) ] - {v}_{N} {σ}_{N} [ N {F}_{tD} - \frac{( 1 - {F}_{t D} ) {n}_{i}}{{F}_{d e g}} exp ( \frac{{E}_{i} - {E}_{t D}}{{k}_{B} T} ) ] \qquad Eq . 1$$

where F_{tD} is the occupation probability of traps, v_{P} and v_{N} denote thermal velocities for holes and electrons, respectively; σ_{P} and σ_{N} are the trap capture cross-sections for holes and electrons, respectively; P and N represent the concentrations of free holes and electrons, respectively; F_{deg} is a degeneracy factor; nᵢ is the intrinsic carrier concentration of the waveguide 212; E_{tD} and Eᵢ are the traps and intrinsic energy levels, respectively. There are four terms on the right side of Eq. 2: 1) a charge rate by capturing valence band holes (e.g., V_{PσP}P(1−F_{tD})), 2) a discharge rate to the valence band

$$( e . g . , {v}_{P} {σ}_{P} {F}_{d e g} {F}_{tD} {n}_{i} exp ( \frac{{E}_{t D} - {E}_{i}}{{k}_{B} T} ) ) ,$$

3) a discharge rate through conduction band electrons (e.g., v_{N}σ_{N}NF_{tD}), and 4) a charge rate due to the emission of electrons to the conduction band

$$( e . g . , {v}_{N} {σ}_{N} \frac{( 1 - {F}_{t D} ) {n}_{i}}{{F}_{d e g}} exp ( \frac{{E}_{i} - {E}_{t D}}{{k}_{B} T} ) ) ,$$

These charge/discharge rates can linearly depend on the trap cross-sections σ_{P} and σ_{N}, which describe the interaction between carriers and traps. Therefore, σ_{P} and σ_{N} can be functions of trap location distance d into the amorphous layer, which can be provided as:

$${σ}_{P} ( d ) = {σ}_{P 0} exp ( - {κ}_{h} d ) \qquad Eq . 2$$

$${σ}_{N} ( d ) = {σ}_{N 0} exp ( - {κ}_{e} d ) \qquad Eq . 3$$

where the σ_{P0} and σ_{N0} are constants that may be, in an example, approximately 10⁻¹⁵ cm² and 10⁻¹⁷ cm², respectively. Kh and Ke are evanescent wavectors for electrons and holes, which can be provided as:

$${κ}_{h}^{2} = \frac{2 {m}_{h}^{*} ( {E}_{tD} - {E}_{V} )}{{ℏ}^{2}} \qquad Eq . 4$$

$${κ}_{e}^{2} = \frac{2 {m}_{e}^{*} ( {E}_{C} - {E}_{tD} )}{{ℏ}^{2}} \qquad Eq . 5$$

where mₕ* and mₑ* are effective masses of holes and electrons, respectively; E_{V} and E_{C} stand for the conduction band edge and valence band edge, respectively. In some examples simulations, the trap spatial density can be assumed to be uniform up to a certain depth and zero above that depth, and the traps can be considered to be monoenergetic.

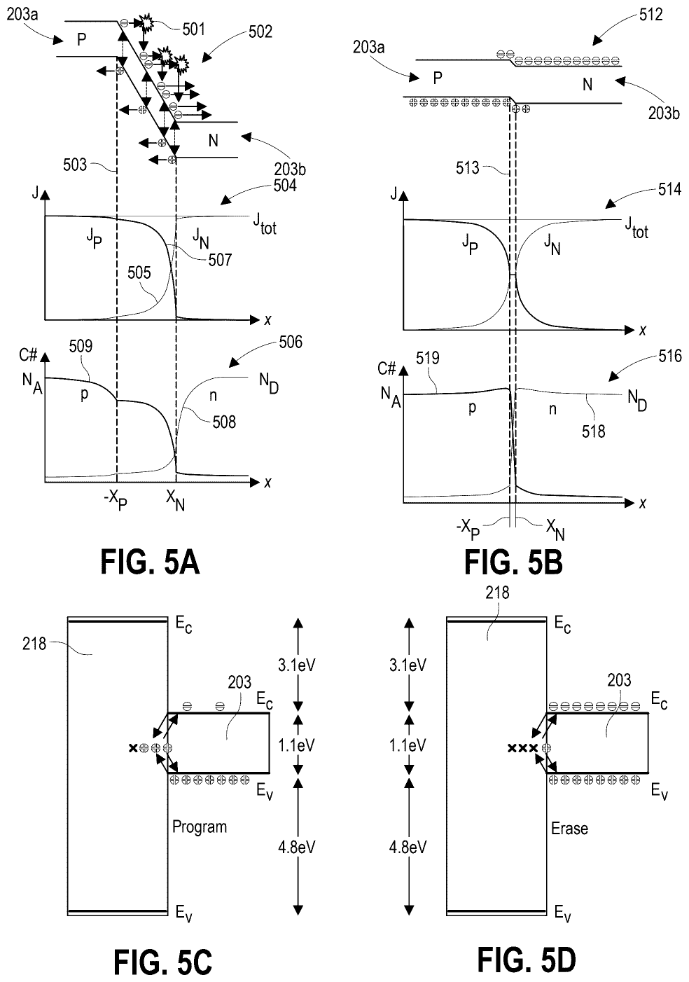

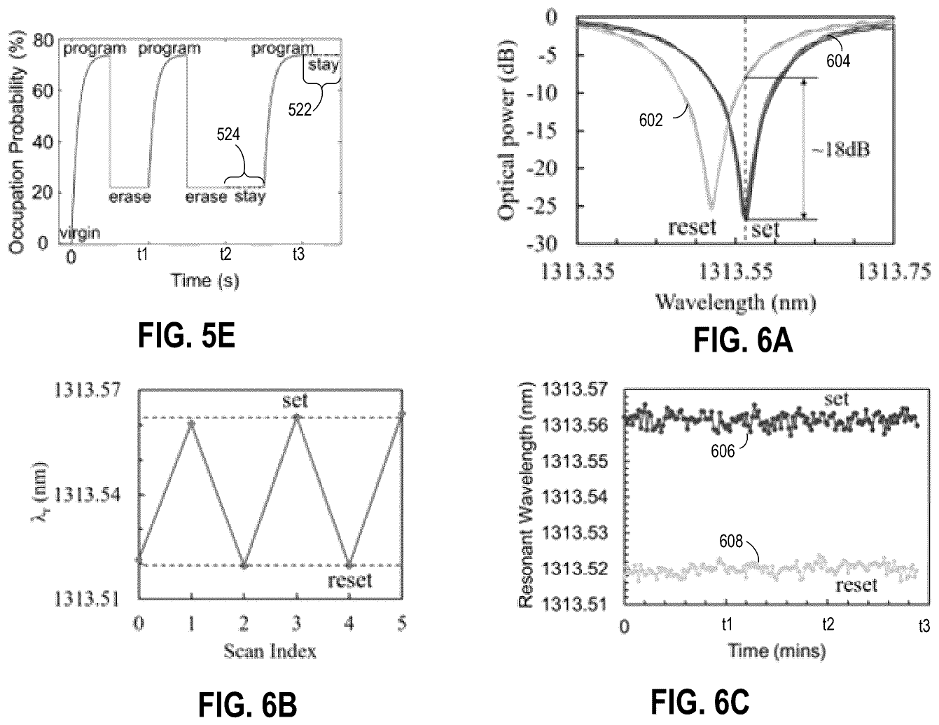

FIG. 5A illustrates an example band diagram 502, current density distribution 504, and free charge carrier concentrations 506 of an example PN junction during a set operation in accordance with examples disclosed herein. FIG. 5B illustrates an example band diagram 512, current density distribution 514, and free charge carrier concentrations 516 of the example PN junction during a set operation in accordance with examples disclosed herein. In the examples of FIGS. 5A and 5B, the PN junction may be PN junction 216 of FIGS. 2A and 2B, in which portion 203b is doped with n-type dopants and portion 203a is doped with p-type dopants.

In the examples, when a reverse bias at approximately the breakdown voltage is applied to the PN junction, avalanche gain can occur inside the depletion region 503 (illustratively depicted as dotted lines) at the depletion interface (e.g., interface 213). Photon-generated carriers can accelerate within the depletion region due to the high electric field, leading to the impact ionization events (an example of which is shown as impact ionization event 501). Due to the significant difference between the ionization coefficients of holes (β) and electrons (α) in the crystalline semiconductor material, impact ionization events can predominantly occur in electrons (illustratively shown as the “−”), as shown in FIG. 5A.

The current density distribution 504 is shown in FIG. 5A as current density J as a function of lateral location x in the PN junction. The portion of the total current density (Jₜₒₜ) contributed by electrons, J_{N}, exhibits an exponential-like growth from left to right due to the increasing number of impact ionization-generated electrons, shown as curve 505. As the current density is uniform across the PN junction, the complementary hole current density, J_{P}, is represented as curve 507. The average J_{P} is greater than the average J_{N} inside the depletion region 503 because of the electron-preferred impact ionization.

The free charge carrier concentrations 506 is shown in FIG. 5A as carrier concentration (C #) as a function of lateral location x in the PN junction. The electron and hole concentration can be extracted from the current density. For example, the electron concentration equals J_{N} divided by qV_{dN} and concentration equals J_{P} divided by qV_{dP}, where V_{dN} and V_{dP} are the drift velocities of the electrons and holes and q is the elementary charge. The elementary charge in this example may be approximately 1.602e¹⁹ coulombs. As the average J_{P} is greater than the average J_{N} in the depletion region 503 and Van is greater than V_{dP}, the hole concentration N_{A} (curve 509) can be higher than the electron concentration N_{D} (curve 508) inside the depletion region 503. Therefore, the first term on the right side of Eq. 2, V_{PσP}P(1−F_{tD}), may dominate the transient behavior and the carrier traps can be charged by capturing excess holes.

Conversely, the PN junction can be forward biased to erase/reset the device. In this case, as shown in FIG. 5B, J_{N} and J_{P} may be almost at the same level due to the similar electron and hole concentrations in depletion region 513, shown in free charge carrier concentrations 516 as curves 518 and 519, respectively. Therefore, the discharge term of Eq. 2 contributed by electrons (term 2 described above) may not be negligible and the rate equation will lead to a new balance state with a smaller F_{tD}.

FIGS. 5C and 5D illustrates band diagrams of an example insulating interface during set and reset operations, in accordance with the examples disclosed herein. While FIGS. 5A and 5B and FIGS. 5C and 5D each show band diagrams, they are presented in different formats so to illustrate particular aspects of the respective band (e.g., FIGS. 5A and 5B show band diagrams of the PN junction to demonstrate carrier distribution therein, while FIGS. 5C and 5D show band diagrams of the insulating interface to illustrate how carriers are trapped/lost due to surface defects). In the examples of FIGS. 5C and 5D, the insulating interface is shown as interface 219 of FIGS. 2A and 2B, such that FIGS. 5C and 5D depict the interface between device layer 203 formed of a crystalline semiconductor material (e.g., Si in this example) and insulating layer 218 formed of an amorphous material (e.g., SiO₂ in this example). FIG. 5C depicts a set operation and FIG. 5B depicts a reset operation. In the examples of FIGS. 5C and 5D, traps (shown as “x”) are charged due to the higher concentration of holes (shown as “+”) during the program operation, and they are discharged as the concentration of holes approaches the concentration of electrons (shown as “−”) during the erase operation. In the examples of FIGS. 5C and 5D, the energy band for the insulating layer 218 is defined between the conduction energy (E_{C}) and the valence energy (E_{V}) for the insulating layer 218, and the energy band for the device layer 203 is defined between E_{C} and E_{V} for the device layer 203. The electron volts (eV) of the example bands shown in FIGS. 50 and 5D are values for the example implementation in which Si and SiO2 are used as the device layer 203 and the insulating layer 218, respectively. Other values may be utilized depending on the materials used to form the devices disclosed herein.

FIG. 5E illustrates an example occupation probability of traps (F_{tD}) formed in the examples disclosed herein plotted as a function. FIG. 5E may be an example of occupation probability of the optical storage device 200 of FIGS. 2A and 2B. In the virgin state (e.g., upon fabrication), a voltage bias may not be applied and the traps are empty. During the program operation (e.g., set operation), the occupation probability may gradually increase with time. In an example, the saturation time may be on the order of approximately 100 s. During the erase operation, the traps may be discharged. The erase speed may be faster than the program due to the higher free carrier concentrations. In the example of FIG. 5E, F_{tD} quickly reduced from approximately 74% to 22%, and then reaches a steady state. Non-volatility is shown in which a steady state is maintained after the erase and program operations (e.g., lines 522 and 524), where there is no bias and current through the device. The occupation probability of traps remains substantially constant without voltage.

FIG. 6A depicts examples of resonance frequencies, in accordance with examples disclosed herein, in a reset state and a set state. For example, FIG. 6A illustrates a first optical spectrum 602 corresponding to a first resonance frequency of a resonator structure 215 while in a reset state. In this case, the first optical spectrum 602 may have a peak resonant wavelength of approximately 1313.51 nm, which corresponds to the first resonance frequency (e.g., speed of light divided by frequency equal wavelength). When the optical storage device 200 is in a reset state, light propagating at an input wavelength corresponding to the first resonance frequency may resonate in the resonator structure 215 and a peak optical power (e.g., a first amplitude) may be output from the bus waveguide 202 and detected (e.g., by a photodetector). Once the optical storage device 200 is programmed and placed in set state, as described above, the resonance frequency of the resonator structure 215 is red shifted, in this example, to second optical spectrum 604. In this case, the second optical spectrum 604 may have a peak resonant wavelength of approximately 1313.57 nm, which corresponds to the second resonance frequency (e.g., speed of light divided by frequency equal wavelength). Thus, light propagating in the resonator structure 215 at the input wavelength experiences increased optical loss due to a mismatch with the resonance frequency. As a result, the output from the bus waveguide 202 may be detected having a second amplitude, that is less than the first amplitude. As can be seen from FIG. 6A, the set state results in resonant wavelength shift of approximately 42 μm with an extinction ratio (ER) of approximately 18 dB. The corresponding resonant wavelength (λᵣ) is shown in FIG. 6B.

FIG. 6C depicts an example retention capability of the optical storage devices disclosed herein. Particularly, FIG. 6C depicts that the resonant wavelength over time in both the set state (plot 606) and reset state (graph 608) after the reset voltage bias is removed. As shown, both states demonstrate stable resonant wavelengths for at least 24 hours.

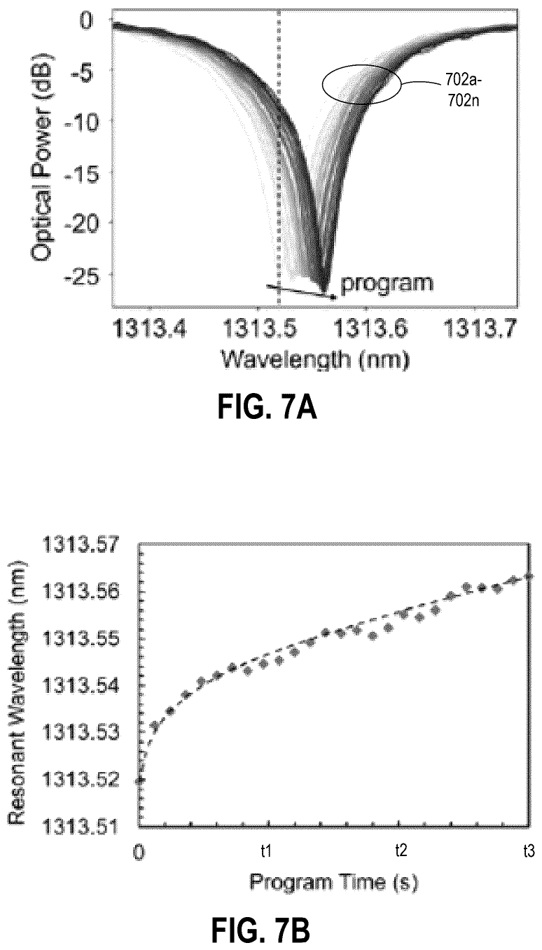

Examples of the optical storage devices disclosed herein can provide for multi-level non-volatile resonant wavelength shifts with a single device. Said another way, the optical storage devices disclosed above (e.g., optical storage device 100 and/or 200) may be programmed to any one of a number of different states, each state corresponding to a different resonant wavelength. For example, the magnitude of the resonant wavelength shift may increase proportionally with an amount of time that the first voltage bias is applied to the optical storage device during a set operation. Thus, applying the first voltage bias (e.g., setting voltage bias) for a first period of time may cause a shift in resonant wavelength of a first magnitude (e.g., approximately 42 pm as shown in FIG. 6A), while applying the applying the first voltage bias for a second period of time (e.g., longer than the first period of time) may result in a larger shift. As an illustrative example, FIG. 7A illustrates a number of states, each corresponding to a different resonant wavelength, that can be achieved by the optical storage device 200. For example, FIG. 7A depicts a plurality of optical spectrums 702a-702n, each corresponding to a programmed state as a function of time over which the first voltage bias is applied. Each optical spectrum has a peak wavelength that is red-shifted relative to a preceding spectrum. By withdrawing the first voltage bias at different times, different programmed states can be achieved. FIG. 7B depicts the change in resonant wavelength (e.g., peak wavelength of FIG. 7A) over time (e.g., program time corresponding to an amount of time that the bias voltage is applied). Thus, in the example of FIGS. 7A and 7B, different states may be achievable using a single device. In some examples, 26 states (e.g., 26 different wavelengths) may be achieved using a single device.

In various examples, the optical storage devices disclosed herein can enable direct integration of optical memory functionality into existing semiconductor photonic systems. For instance, traditional MRR-based optical interconnects encounter a challenge in fabrication variances, as the resonant wavelength of MRR is sensitive to such variances. Fine-tuning may be necessary to align the MRR resonant wavelength precisely and avoid channel crosstalk. However, leveraging the optical storage devices of the present disclosure, such as optical storage system 100 and/or optical storage device 200, the trimming process can be streamlined because the program/erase processes the disclosed devices does not interfere with the volatile tuning of the traditional MRRs. Consequently, a need for energy-intensive thermal tuning may be eliminated in current optical interconnects.

Another example application may be in optical neural networks (ONNs), which recently has garnered significant interest due to its potential to drastically boost speed and energy efficiency by several orders of magnitude. The lack of optical memory in the conventional technologies can create a wall between an ONN chip and electrical memory, limiting the realization of their full potential in terms of speed and efficiency. The examples disclosed herein can offer a solution to overcome this bottleneck.

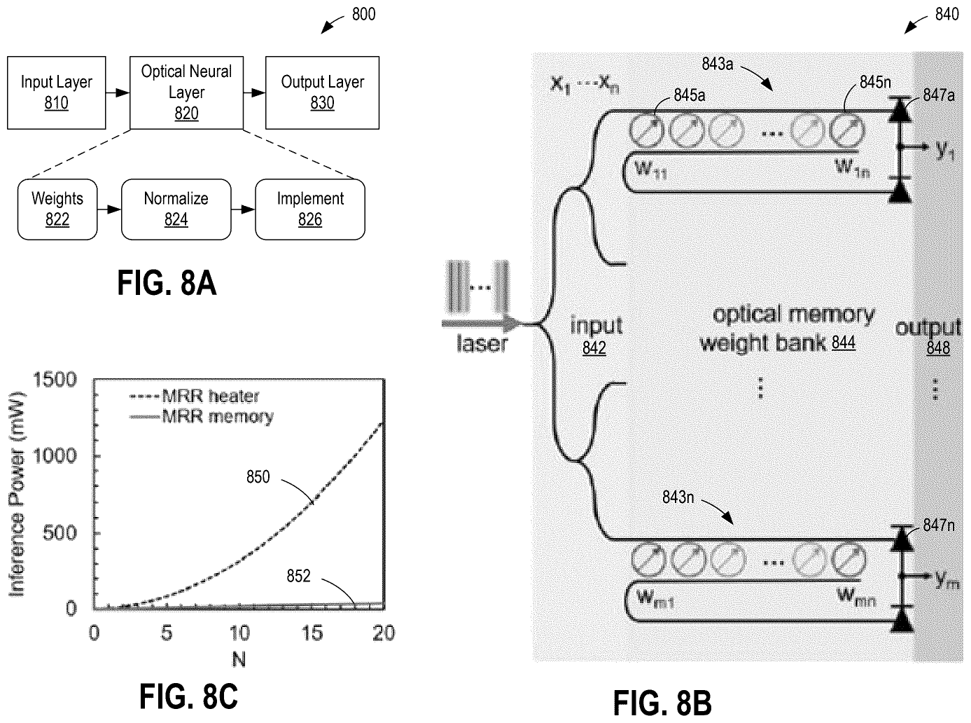

FIGS. 8A-8C depict an example ONN utilizing the optical storage devices disclosed herein (e.g., optical storage system 100 and/or optical storage device 200).

FIG. 8A is a schematic diagram of an example neural layer 800. The neural layer 800 comprises an input layer 810, an optical neural layer 820, and an output layer 830. The optical neural layer 820 may obtain weights by training 822, normalize the weights 824, and implement the weights 826, for example, using an optical weight bank according to the examples herein. For example, optical neural layer 820 may use an optical weight bank comprise one or more non-volatile optical storage devices (e.g., optical storage device 112 and/or optical storage device 200). Each non-volatile optical storage device may be can be programmed (e.g., set) to one of weights 826 through selective control of resonant frequency in a manner described above in connection with FIGS. 1-4B.

FIG. 8B depicts an example implementation of an optical matrix-vector multiplier 840 employing an optical memory weight bank 844 according to the examples disclosed herein. The optical matrix-vector multiplier 840 may be an example implementation of neural layer 800, where the optical memory weight bank 8414 may be an example of implementing trained weight 826. For example, as detailed below, the optical memory weight bank 844 may comprise one or more one or more non-volatile optical storage devices (e.g., optical storage device 112 and/or optical storage device 200), each of which can be programmed (e.g., set) to one of weights 826 through selective control of resonant frequency in a manner described above in connection with FIGS. 1-4B.

In FIG. 8B, an input optical source (e.g., a comb laser) can be input signals that are cascaded to a plurality of legs 843a-843n at the input layer 842 (e.g., input layer 810). In an example, the input layer 842 may employ wavelength division multiplexed (WDM) that provides WDM signals as input signals that are coupled to various legs 843a-843n of the optical memory weight bank 844 via optical splitters or the like. The input signals can be weighted by the optical memory weight bank 844, which comprises a plurality of optical memory devices that are reconfigurable for realizing multiplication. Optical memory devices 845a-845n are shown as part of leg 843a as an illustrative example. Each leg 843a-843n comprises a corresponding set of optical memory devices. The weighted signals can be accumulated by balanced photodiodes 847a-847n, which provides results of the multiplication as output signals at the output layer 848. For example, each set of optical storage devices corresponding to a given leg may supply weighted optical signals to the balanced photodiodes 847a-847n, which accumulates the optical signals to output a result of the matrix-vector multiplication. In some examples, the results can be provided to an activation function, as known in the art.

In examples, trained weights can be encoded into the plurality of optical memory devices. For example, each optical storage device can be programmed (e.g., set) to a trained weight of the matrix-vector multiplication through selective control of resonant frequency in a manner described above in connection with FIGS. 1-4B. That is, each optical memory device can be tuned to a desired resonant frequency that encodes the trained weight into the optical memory device. Tuning can be performed, for example with reference to FIG. 4A, by applying first voltage bias 402 while supplying optical signal 404 to optical storage device 200. Each optical memory device can be tuned to different resonant frequencies, as desired, to achieve different weights by applying the first voltage for different amounts of time, as described above in connection with FIGS. 7A-7C.

FIG. 8C depicts power consumed in performing an inference (e.g. optical matrix-vector multiplication) by a conventional optical storage device (e.g., a heater-based phased shifter coupled to an MRR for setting weights) compared to an optical storage device according to the present disclosure. FIG. 8C shows power consumed in milliwatts as a function of a number N of optical storage devices. The power consumption of conventional heater-based MRR weights increases with N², dominating the overall power consumption of the inference. In contrast, the power consumption by examples disclosed is from the optical source inputting the input signals and the receivers (e.g., photodiodes, thus the power consumption by the examples disclosed herein increases linearly with N. Thus, as shown in FIG. 8C, the power consumed by the conventional heat-based MRR (curve 850) is significantly more than the power consumed by the examples disclosed herein (curve 852).

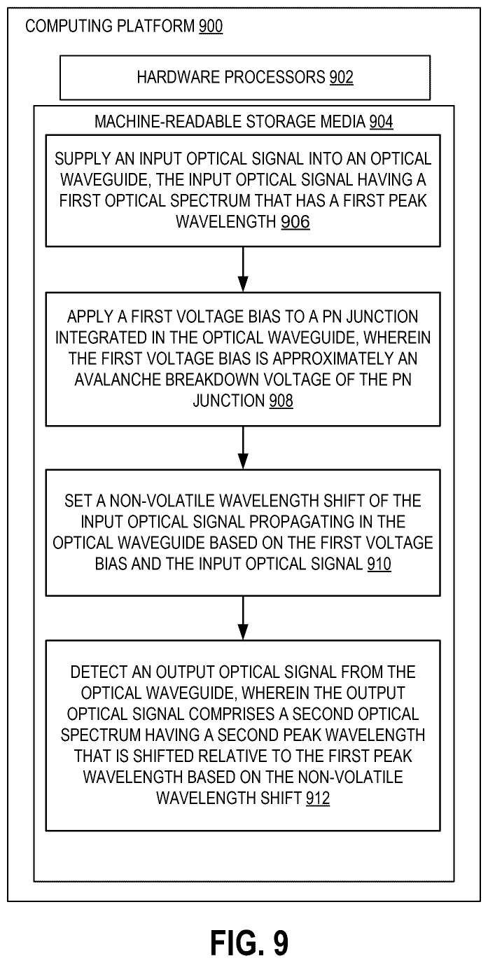

FIG. 9 illustrates a computing component that may be used to implement non-volatile optical storage in accordance with various examples of the disclosed technology. Referring now to FIG. 9, computing component 900 may be, for example, a server computer, a controller, or any other similar computing component capable of processing data. In the example implementation of FIG. 9, the computing component 900 includes a hardware processor 902, and machine-readable storage medium for 904.

Hardware processor 902 may be one or more central processing units (CPUs), semiconductor-based microprocessors, and/or other hardware devices suitable for retrieval and execution of instructions stored in machine-readable storage medium 904. Hardware processor 902 may fetch, decode, and execute instructions, such as instructions 906-912, to control processes or operations for non-volatile optical storage. As an alternative or in addition to retrieving and executing instructions, hardware processor 902 may include one or more electronic circuits that include electronic components for performing the functionality of one or more instructions, such as a field programmable gate array (FPGA), application specific integrated circuit (ASIC), or other electronic circuits.

A machine-readable storage medium, such as machine-readable storage medium 904, may be any electronic, magnetic, optical, or other physical storage device that contains or stores executable instructions. Thus, machine-readable storage medium 904 may be, for example, Random Access Memory (RAM), non-volatile RAM (NVRAM), an Electrically Erasable Programmable Read-Only Memory (EEPROM), a storage device, an optical disc, and the like. In some examples, machine-readable storage medium 904 may be a non-transitory storage medium, where the term “non-transitory” does not encompass transitory propagating signals. As described in detail below, machine-readable storage medium 904 may be encoded with executable instructions, for example, instructions 906-912.

Hardware processor 902 may execute instruction 906 to supply an input optical signal into an optical waveguide. The input optical signal may have an input optical spectrum that has a peak wavelength. In some examples, the input optical signal may be emitted by an optical source, such as an O-band laser or other optical source as described above. In an example implementation, the input optical spectrum may correspond to a first resonant frequency, such as optical spectrum 602 of FIG. 6A. In some examples, the optical waveguide may be, for example, optical waveguide 114 of optical storage system 100 and/or optical waveguide 214 of optical storage device 200 described above. In an example, the input optical signal may be coupled into a bus waveguide (e.g., bus waveguide 102 and/or 202), which may be configured to evanescently couple the input light into the optical waveguide. As described above in connection with FIGS. 2A and 2B, the optical waveguide 214 may be a closed loop waveguide that provides for a resonator structure 215 having a resonant frequency that enables the input optical signal to resonate in the resonator structure 215. In some examples, the resonator structure 215 may be an MRR. At this point, light resonates within the resonator structure 215 and can be detected at the output of the bus waveguide having an optical power at a first amplitude.

Hardware processor 902 may execute instruction 908 to apply a first voltage bias to a PN junction integrated in the optical waveguide. The first voltage bias may be approximately an avalanche breakdown voltage of the PN junction, according to an example implementation. In some examples, instruction 908 may provide a control signal to a power source (e.g., power sources 108 and/or 208) that control the power source to supply the first voltage bias to the PN junction. The first voltage bias, according to various examples, may be a reverse bias. The PN junction, according to various examples, can be formed within the body of the optical waveguide, for example, by doping a first portion (e.g., portion 203a) with a first dopant type (e.g., p-type dopants) and a second portion (e.g., portion 203b) with a second dopant type of opposing polarity (e.g., p-type dopants).

In examples, instructions 908 may comprise applying the first voltage bias to the PN junction while the input optical signal is input into the optical waveguide (e.g., at the same time or otherwise simultaneously). Both the first voltage bias and the input optical signal need not be triggered at the same time, only that there is an overlap in time as to when both conditions are applied to the device.

Hardware processor 902 may execute instruction 910 to set a non-volatile refractive index change of the optical waveguide based on the first voltage bias and the input optical signal. For example, as detailed above, optical waveguide may comprise a crystalline semiconductor material (e.g., crystalline Si) and an amorphous material (e.g., amorphous SiO₂) may be disposed on the crystalline semiconductor material to forming an imperfect interface therebetween. Carrier traps are formed in the imperfect interface. An accumulation of free charge carriers results at a depletion interface of the PN junction due to the input optical signal and the first voltage bias that cause a photon-induced avalanche effect. As the concentration of free charge carriers increases in the PN junction, the free charge carriers can be captured in the traps at the imperfect interface. As filled traps (also referred to as charged traps or trapped carriers) accumulates, the refractive index of the optical waveguide changes and, ultimately, the resonant wavelength of the optical waveguide shifts. Instructions 910 may comprise providing a control signal that turns off the first voltage bias and/or the input optical signal that sets a magnitude of the non-volatile resonate wavelength shift (e.g., programs the device) based on an amount of time that both the first voltage bias and input optical signal were simultaneously present within the optical waveguide. In some examples, the magnitude of the non-volatile resonate wavelength shift may be tuned based on the amount of overlap in terms of time.

Hardware processor 902 may execute instruction 912 to detect an output optical signal from the optical waveguide. The output optical signal may comprise an optical power having a second amplitude that is change relative to a first amplitude based on the non-volatile refractive index change. In some examples, the optical signal may be coupled from the optical waveguide into the bus waveguide, which can emit the optical signal to a photodetector (e.g., second optical device 106 in FIG. 1). The photodetector may detect the output having the second amplitude.

The above example described in connection with FIG. 9 may be applicable to a plurality of optical memory devices, such as those described in connection with FIGS. 8A-8C. That is, for example, hardware processor 902 may execute instructions 906-910 for each of the plurality of optical memory devices of optical memory weight bank 844. By tuning the wavelength shift for each optical memory device, trained weights can be encoded into the optical memory bank for performing neural tasks as described above.

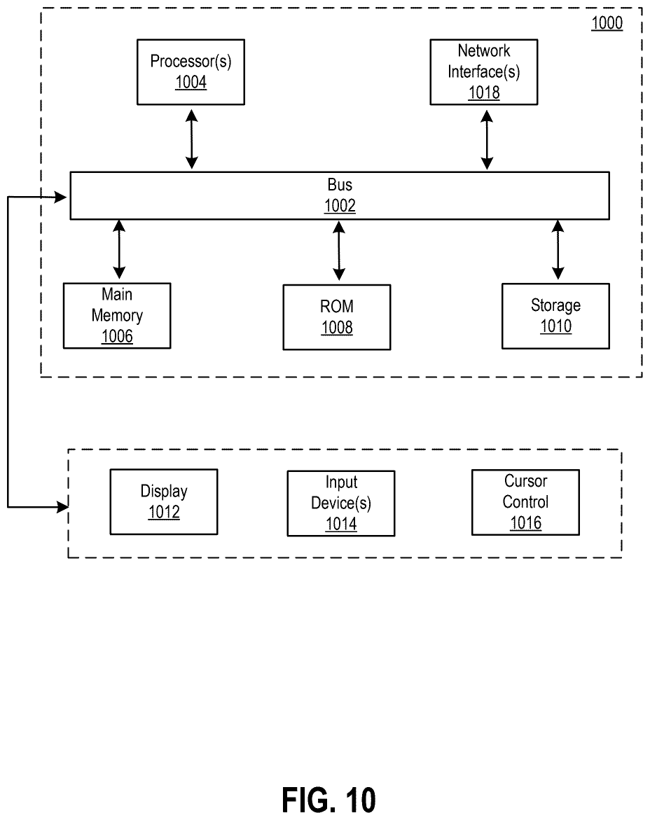

FIG. 10 depicts a block diagram of an example computer system 1000 in which various examples of the disclosed technology described herein may be implemented. The computer system 1000 includes a bus 1002 or other communication mechanism for communicating information, one or more hardware processors 1004 coupled with bus 1002 for processing information. Hardware processor(s) 1004 may be, for example, one or more general purpose microprocessors. In an example, control circuit 110 of FIG. 1, may be implemented as the computer system 1000.

The computer system 1000 also includes a main memory 1006, such as a random access memory (RAM), cache and/or other dynamic storage devices, coupled to bus 1002 for storing information and instructions to be executed by processor 1004. Main memory 1006 also may be used for storing temporary variables or other intermediate information during execution of instructions to be executed by processor 1004. Such instructions, when stored in storage media accessible to processor 1004, render computer system 1000 into a special-purpose machine that is customized to perform the operations specified in the instructions. For example, main memory 1006 may store instructions, that when executed by processor(s) 1004, cause computer system 1000 to perform one or more of the operations described in connection with FIG. 9.

The computer system 1000 further includes a read only memory (ROM) 1008 or other static storage device coupled to bus 1002 for storing static information and instructions for processor 1004. A storage device 1010, such as a magnetic disk, optical disk, or USB thumb drive (Flash drive), etc., is provided and coupled to bus 1002 for storing information and instructions.

The computer system 1000 may be coupled via bus 1002 to a display 1012, such as a liquid crystal display (LCD) (or touch screen), for displaying information to a computer user. An input device 1014, including alphanumeric and other keys, is coupled to bus 1002 for communicating information and command selections to processor 1004. Another type of user input device is cursor control 1016, such as a mouse, a trackball, or cursor direction keys for communicating direction information and command selections to processor 1004 and for controlling cursor movement on display 1012. In some examples, the same direction information and command selections as cursor control may be implemented via receiving touches on a touch screen without a cursor.

The computing system 1000 may include a user interface module to implement a GUI that may be stored in a mass storage device as executable software codes that are executed by the computing device(s). This and other modules may include, by way of example, components, such as software components, object-oriented software components, class components and task components, processes, functions, attributes, procedures, subroutines, segments of program code, drivers, firmware, microcode, circuitry, data, databases, data structures, tables, arrays, and variables.

In general, the word “component,” “engine,” “system,” “database,” data store,” and the like, as used herein, can refer to logic embodied in hardware or firmware, or to a collection of software instructions, possibly having entry and exit points, written in a programming language, such as, for example, Java, C or C++. A software component may be compiled and linked into an executable program, installed in a dynamic link library, or may be written in an interpreted programming language such as, for example, BASIC, Perl, or Python. It will be appreciated that software components may be callable from other components or from themselves, and/or may be invoked in response to detected events or interrupts. Software components configured for execution on computing devices may be provided on a computer readable medium, such as a compact disc, digital video disc, flash drive, magnetic disc, or any other tangible medium, or as a digital download (and may be originally stored in a compressed or installable format that requires installation, decompression or decryption prior to execution). Such software code may be stored, partially or fully, on a memory device of the executing computing device, for execution by the computing device. Software instructions may be embedded in firmware, such as an EPROM. It will be further appreciated that hardware components may be comprised of connected logic units, such as gates and flip-flops, and/or may be comprised of programmable units, such as programmable gate arrays or processors.

The computer system 1000 may implement the techniques described herein using customized hard-wired logic, one or more ASICs or FPGAs, firmware and/or program logic which in combination with the computer system causes or programs computer system 1000 to be a special-purpose machine. According to one example of the disclosed technology, the techniques herein are performed by computer system 1000 in response to processor(s) 1004 executing one or more sequences of one or more instructions contained in main memory 1006. Such instructions may be read into main memory 1006 from another storage medium, such as storage device 1010. Execution of the sequences of instructions contained in main memory 1006 causes processor(s) 1004 to perform the process steps described herein. In alternative examples, hard-wired circuitry may be used in place of or in combination with software instructions.

The term “non-transitory media,” and similar terms, as used herein refers to any media that store data and/or instructions that cause a machine to operate in a specific fashion. Such non-transitory media may comprise non-volatile media and/or volatile media. Non-volatile media includes, for example, optical or magnetic disks, such as storage device 1010. Volatile media includes dynamic memory, such as main memory 1006. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM, NVRAM, any other memory chip or cartridge, and networked versions of the same.

Non-transitory media is distinct from but may be used in conjunction with transmission media. Transmission media participates in transferring information between non-transitory media. For example, transmission media includes coaxial cables, copper wire and fiber optics, including the wires that comprise bus 1002. Transmission media can also take the form of acoustic or light waves, such as those generated during radio-wave and infra-red data communications.

The computer system 1000 also includes a network interface 1018 (also referred to as a communication interface) coupled to bus 1002. Network interface 1018 provides a two-way data communication coupling to one or more network links that are connected to one or more local networks. For example, network interface 1018 may be an integrated services digital network (ISDN) card, cable modem, satellite modem, or a modem to provide a data communication connection to a corresponding type of telephone line. As another example, network interface 1018 may be a local area network (LAN) card to provide a data communication connection to a compatible LAN (or WAN component to communicate with a WAN). Wireless links may also be implemented. In any such implementation, network interface 1018 sends and receives electrical, electromagnetic or optical signals that carry digital data streams representing various types of information.

A network link typically provides data communication through one or more networks to other data devices. For example, a network link may provide a connection through local network to a host computer or to data equipment operated by an Internet Service Provider (ISP). The ISP in turn provides data communication services through the world wide packet data communication network now commonly referred to as the “Internet.” Local network and Internet both use electrical, electromagnetic or optical signals that carry digital data streams. The signals through the various networks and the signals on network link and through network interface 1018, which carry the digital data to and from computer system 1000, are example forms of transmission media.

The computer system 1000 can send messages and receive data, including program code, through the network(s), network link and network interface 1018. In the Internet example, a server might transmit a requested code for an application program through the Internet, the ISP, the local network and the network interface 1018.

The received code may be executed by processor 1004 as it is received, and/or stored in storage device 1010, or other non-volatile storage for later execution.

Each of the processes, methods, and algorithms described in the preceding sections may be embodied in, and fully or partially automated by, code components executed by one or more computer systems or computer processors comprising computer hardware. The one or more computer systems or computer processors may also operate to support performance of the relevant operations in a “cloud computing” environment or as a “software as a service” (SaaS). The processes and algorithms may be implemented partially or wholly in application-specific circuitry. The various features and processes described above may be used independently of one another, or may be combined in various ways. Different combinations and sub-combinations are intended to fall within the scope of this disclosure, and certain method or process blocks may be omitted in some implementations. The methods and processes described herein are also not limited to any particular sequence, and the blocks or states relating thereto can be performed in other sequences that are appropriate, or may be performed in parallel, or in some other manner. Blocks or states may be added to or removed from the disclosed examples. The performance of certain of the operations or processes may be distributed among computer systems or computers processors, not only residing within a single machine, but deployed across a number of machines.

As used herein, a circuit might be implemented utilizing any form of hardware, software, or a combination thereof. For example, one or more processors, controllers, ASICs, PLAS, PALs, CPLDs, FPGAs, logical components, software routines or other mechanisms might be implemented to make up a circuit. In implementation, the various circuits described herein might be implemented as discrete circuits or the functions and features described can be shared in part or in total among one or more circuits. Even though various features or elements of functionality may be individually described or claimed as separate circuits, these features and functionality can be shared among one or more common circuits, and such description shall not require or imply that separate circuits are required to implement such features or functionality. Where a circuit is implemented in whole or in part using software, such software can be implemented to operate with a computing or processing system capable of carrying out the functionality described with respect thereto, such as computer system 1000.

As used herein, the term “or” may be construed in either an inclusive or exclusive sense. Moreover, the description of resources, operations, or structures in the singular shall not be read to exclude the plural. Conditional language, such as, among others, “can,” “could,” “might,” or “may,” unless specifically stated otherwise, or otherwise understood within the context as used, is generally intended to convey that certain examples include, while other examples do not include, certain features, elements and/or steps.

Terms and phrases used in this document, and variations thereof, unless otherwise expressly stated, should be construed as open ended as opposed to limiting. Adjectives such as “conventional,” “traditional,” “normal,” “standard,” “known,” and terms of similar meaning should not be construed as limiting the item described to a given time period or to an item available as of a given time, but instead should be read to encompass conventional, traditional, normal, or standard technologies that may be available or known now or at any time in the future. The presence of broadening words and phrases such as “one or more,” “at least,” “but not limited to” or other like phrases in some instances shall not be read to mean that the narrower case is intended or required in instances where such broadening phrases may be absent.

What is claimed is:

1. An optical device comprising:
a crystalline semiconductor layer disposed on a substrate, the crystalline semiconductor layer comprising an optical waveguide and a PN junction formed in the optical waveguide;
an amorphous layer disposed on the crystalline semiconductor layer;
an optical source configured to emit light of a wavelength into the optical waveguide; and
a power source configured to:
supply a first voltage bias across the PN junction that causes an amplitude of optical power of light emitted from the optical waveguide to change from a first amplitude to a second amplitude, wherein the optical waveguide emits light at the second amplitude while the first voltage bias is supplied and after the first voltage bias is removed.

2. The optical device of claim 1, wherein the power source is further configured to, after applying the first voltage bias, apply a second voltage bias across the PN junction that causes the optical waveguide to emit light at the wavelength.

3. The optical device of claim 2, wherein the optical waveguide emits the light at the wavelength while the second voltage bias is applied and after the second voltage bias is removed from the PN junction.

4. The optical device of claim 1, further comprising:
a bus waveguide optically coupled to the optical waveguide and configured to optically couple the light emitting from the optical source into the optical waveguide at the wavelength.

5. The optical device of claim 1, further comprising:
a resonator structure formed on the substrate, wherein the resonator structure comprises the optical waveguide and the PN junction.

6. The optical device of claim 5, wherein the resonator structure is a micro-ring resonator.

7. The optical device of claim 1, wherein the crystalline semiconductor layer comprises silicon, and wherein the amorphous layer comprises silicon dioxide.

8. The optical device of claim 1, wherein applying the first voltage bias tunes a refractive index of the optical waveguide by causing carriers to be trapped at an interface between the crystalline semiconductor layer and the amorphous layer.

9. The optical device of claim 8, wherein the first voltage bias is applied at approximately an avalanche breakdown voltage of the PN junction, wherein the first voltage bias causes an accumulation of carriers within the PN junction, wherein and the carriers are trapped at the interface between crystalline semiconductor layer and the amorphous layer.

10. A method comprising:
supplying an input optical signal into an optical waveguide;
applying a first voltage bias to a PN junction integrated in the optical waveguide, wherein the first voltage bias is approximately an avalanche breakdown voltage of the PN junction;
setting a non-volatile refractive index change of the optical waveguide based on the first voltage bias and the input optical signal; and
detecting, by a photodetector, an output optical signal from the optical waveguide, wherein the output optical signal comprises an optical power having a second amplitude that is changed relative to a first amplitude based on the non-volatile refractive index change.

11. The method of claim 10, further comprising:
after applying the first voltage bias, applying a second voltage bias to the PN junction; and
resetting the non-volatile refractive index change based on the second voltage bias.

12. The method of claim 10, further comprising:
tuning a magnitude of the non-volatile refractive index change based on an amount of time that the first voltage bias is applied to the PN junction.

13. The method of claim 10, wherein the first voltage bias is applied to the PN junction while the input optical signal is input into the optical waveguide.

14. The method of claim 10, wherein optical waveguide comprises a crystalline semiconductor material, wherein an amorphous semiconductor material is disposed on the crystalline semiconductor material.

15. The method of claim 14, wherein a plurality of carrier traps are formed between the crystalline semiconductor material and the amorphous semiconductor material, wherein applying the first voltage bias to the PN junction causes an accumulation of free charge carriers in the optical waveguide, and wherein the free charge carriers are trapped in the carrier traps and causes the non-volatile refractive index change of the optical waveguide.

16. An optical neural network comprising:
an optical memory bank having at least one non-volatile optical storage device, the at least one non-volatile optical storage device comprising:
an optical waveguide,
a PN junction formed in the optical waveguide, and
an insulating layer disposed on the optical waveguide;
an optical source configured to input an optical signal into the optical waveguide at a wavelength; and
a power source configured to:
supply a first voltage bias, while the optical source inputs the optical signal into the optical waveguide, across the PN junction that causes an amplitude of the optical signal in the optical waveguide to shift to from a first amplitude to a second amplitude.

17. The optical neural network of claim 16, wherein the optical waveguide comprises a crystalline semiconductor material and the insulating layer comprises an amorphous semiconductor material.

18. The optical neural network of claim 16, wherein the optical waveguide comprises a first portion doped with a first dopant type and a second portion doped with a second dopant type, wherein the first and second portion form the PN junction.

19. The optical neural network of claim 16, wherein the first voltage bias is applied at approximately an avalanche breakdown voltage of the PN junction.

20. The optical neural network of claim 16, wherein the optical memory bank comprises a plurality of non-volatile optical storage devices, wherein the plurality of non-volatile optical storage device are encoded with weights.
